(19) United States
(12) Patent Application Publication
(10) Pub. No.: US 2022/0173154 A1
(43) Pub. Date: Jun. 2, 2022

(54) DETECTION DEVICE

(71) Applicant: Japan Display Inc., Tokyo (JP)

(72) Inventors: Yoshitaka OZEKI, Tokyo (JP); Satoshi TOKURA, Tokyo (JP)

(21) Appl. No.: 17/674,479

(22) Filed: Feb. 17, 2022

Related U.S. Application Data
(63) Continuation of application No. PCT/JP2020/027276, filed on Jul. 13, 2020.

(30) Foreign Application Priority Data
Aug. 30, 2019 (JP) 2019-158946

(51) Int. Cl. H01L 27/146; H01L 31/0216; H01L 31/105

(52) U.S. Cl. CPC H01L 27/14643; H01L 31/105; H01L 31/02164; H01L 27/14623

(57) ABSTRACT

According to an aspect, a detection device includes: a substrate; a photoelectric conversion element that is provided to the substrate and comprises a semiconductor layer; a transistor that is provided corresponding to the photoelectric conversion element; a first insulating film that is provided on the substrate so as to cover the transistor; and a second insulating film that is provided on the first insulating film so as to cover the photoelectric conversion element and is formed of an organic material.

### CROSS-REFERENCE TO RELATED APPLICATION

The present application is a continuation of PCT patent application no. PCT/JP2020/027276, filed Jul. 13, 2020, which claims priority to Japanese Patent Application No. 2019-158946, filed on Aug. 30, 2019, the entire contents of which are incorporated herein by reference.

### BACKGROUND

### 1. Technical Field

What is disclosed herein relates to a detection device.

### 2. Description of the Related Art

Japanese Patent No. 6028233 (JP-6028233) describes a detection device (photoelectric conversion device in JP-6028233) in which a plurality of photoelectric conversion elements such as positive-intrinsic-negative (PIN) photodiodes are arranged on a substrate. Such an optical detection device is used as, for example, a biometric sensor, such as a fingerprint sensor or a vein sensor, that detects biological information. The photoelectric conversion elements are separately arranged at an arrangement pitch corresponding to a resolution of detection and are covered with inorganic insulating films of, for example, silicon oxide and silicon nitride.

When the photoelectric conversion elements are thickly formed, the covering property of the inorganic insulating films may be lowered. As a result, the reliability of the detection device may deteriorate.

### SUMMARY

According to an aspect, a detection device includes: a substrate; a photoelectric conversion element that is provided to the substrate and comprises a semiconductor layer; a transistor that is provided corresponding to the photoelectric conversion element; a first insulating film that is provided on the substrate so as to cover the transistor; and a second insulating film that is provided on the first insulating film so as to cover the photoelectric conversion element and is formed of an organic material.

### BRIEF DESCRIPTION OF THE DRAWINGS

FIG. 1A is a sectional view illustrating a schematic sectional configuration of a detection apparatus with an illumination device, the detection apparatus including a detection device according to a first embodiment;

FIG. 1B is a sectional view illustrating a schematic sectional configuration of a detection apparatus with an illumination device according to a first modification;

FIG. 2 is a plan view illustrating the detection device according to the first embodiment;

FIG. 3 is a block diagram illustrating a configuration example of the detection device according to the first embodiment;

FIG. 4 is a circuit diagram illustrating a detection element;

FIG. 5 is a timing waveform diagram illustrating an operation example of the detection element;

FIG. 6 is a plan view illustrating the detection element;

FIG. 7 is a VII-VII′ sectional view of FIG. 6;

FIG. 8 is a sectional view illustrating a detection element according to a second modification of the first embodiment;

FIG. 9 is a sectional view illustrating a detection element according to a second embodiment; and

FIG. 10 is a sectional view illustrating a detection element according to a third modification of the second embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the disclosure. To further clarify the description, widths, thicknesses, shapes, and the like of various parts may be schematically illustrated in the drawings as compared with actual aspects thereof. However, they are merely examples, and interpretation of the present disclosure is not limited thereto. The same component as that described with reference to an already mentioned drawing is denoted by the same reference numeral through the description and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

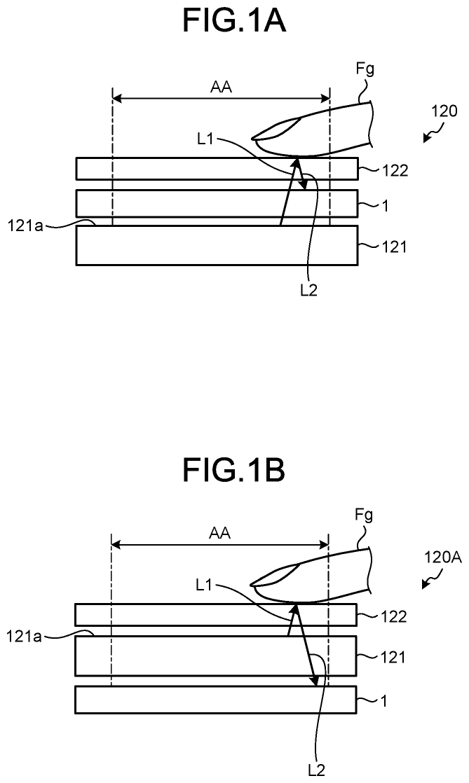

FIG. 1A is a sectional view illustrating a schematic sectional configuration of a detection apparatus with an illumination device, the detection apparatus including a detection device according to a first embodiment. As illustrated in FIG. 1A, a detection apparatus 120 with an illumination device includes a detection device 1, an illumination device 121, and a protective member 122. The illumination device 121, the detection device 1, and the protective member 122 are stacked in this order in a direction orthogonal to a surface of the detection device 1.

The illumination device 121 has a light-emitting surface 121a for emitting light and emits light L1 from the light-emitting surface 121a toward the detection device 1. The illumination device 121 is a backlight. The illumination device 121 may be, for example, what is called a side light-type backlight that includes a light guide plate provided in a position corresponding to a detection region AA and a plurality of light sources arranged at one end or both ends of the light guide plate. For example, light-emitting diodes (LEDs) for emitting light in a predetermined color are used as the light sources. The illumination device 121 may be what is called a direct-type backlight that includes the light sources (such as the LEDs) provided directly below the detection region AA. The illumination device 121 is not limited to the backlight, and may be provided on a lateral side or an upper side of the detection device 1 to emit the light L1 from the lateral side or the upper side of a finger Fg.

The detection device 1 is provided so as to face the light-emitting surface 121a of the illumination device 121. The light L1 emitted from the illumination device 121 passes through the detection device 1 and the protective member 122. The detection device 1 is, for example, a light-reflective biometric sensor, and can detect asperities (such as a fingerprint) on a surface of the finger Fg by detecting light L2 reflected on the finger Fg. Alternatively, the detection device 1 may detect information on a living body by detecting the light L2 reflected inside the finger Fg in addition to detecting the fingerprint. Examples of the information on the living body include a blood vessel image of, for example, a vein, pulsation, and a pulse wave. The color of the light L1 from the illumination device 121 may be varied depending on a detection target.

The protective member 122 is a member for protecting the detection device 1 and the illumination device 121 and covers the detection device 1 and the illumination device 121. The protective member 122 is, for example, a glass substrate. The protective member 122 is not limited to a glass substrate, and may be, for example, a resin substrate. The protective member 122 may be omitted. In this case, the surface of the detection device 1 is provided with a protective layer of, for example, an insulating film, and the finger Fg contacts the protective layer of the detection device 1.

The detection apparatus 120 with an illumination device may be provided with a display panel instead of the illumination device 121. The display panel may be, for example, an organic electroluminescent (EL) diode (organic light-emitting diode (OLED)) panel or an inorganic EL display (micro-LED or mini-LED) panel. Alternatively, the display panel may be a liquid crystal display (LCD) panel using liquid crystal elements as display elements or an electrophoretic display (EPD) panel using electrophoretic elements as display elements. Also in this case, display light (light L1) emitted from the display panel passes through the detection device 1, and the fingerprint of the finger Fg and the information on the living body can be detected based on the light L2 reflected by the finger Fg.

### First Modification

FIG. 1B is a sectional view illustrating a schematic sectional configuration of a detection apparatus with an illumination device according to a first modification. As illustrated in FIG. 1B, in a detection apparatus 120A with an illumination device, the detection device 1, the illumination device 121, the protective member 122 (cover glass) are stacked in this order in the direction orthogonal to the surface of the detection device 1. Also in the present modification, a display panel such as an organic EL display panel can be employed as the illumination device 121.

The light L1 emitted from the illumination device 121 passes through the protective member 122, and then, is reflected by the finger Fg. The light L2 reflected by the finger Fg passes through the protective member 122 and further passes through the illumination device 121. The detection device 1 can perform the detection of the information on the living body such as the fingerprint detection by receiving the light L2 that has passed through the illumination device 121.

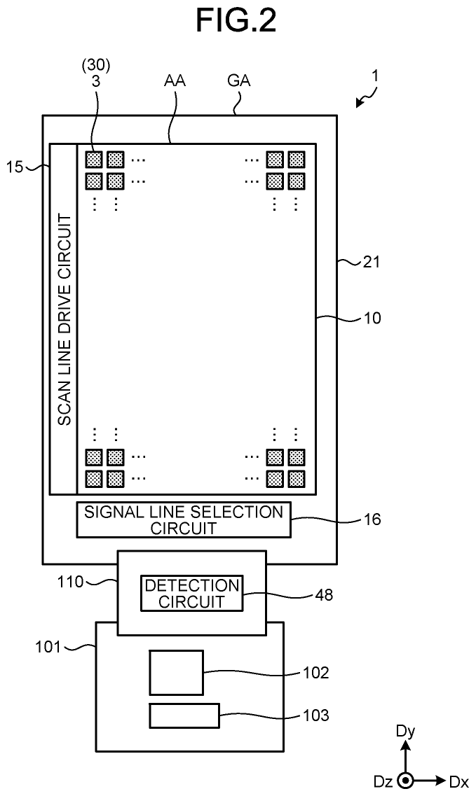

FIG. 2 is a plan view illustrating the detection device according to the first embodiment. As illustrated in FIG. 2, the detection device 1 includes a substrate 21, a sensor 10, a scan line drive circuit 15, a signal line selection circuit 16, a detection circuit 48, a control circuit 102, and a power supply circuit 103.

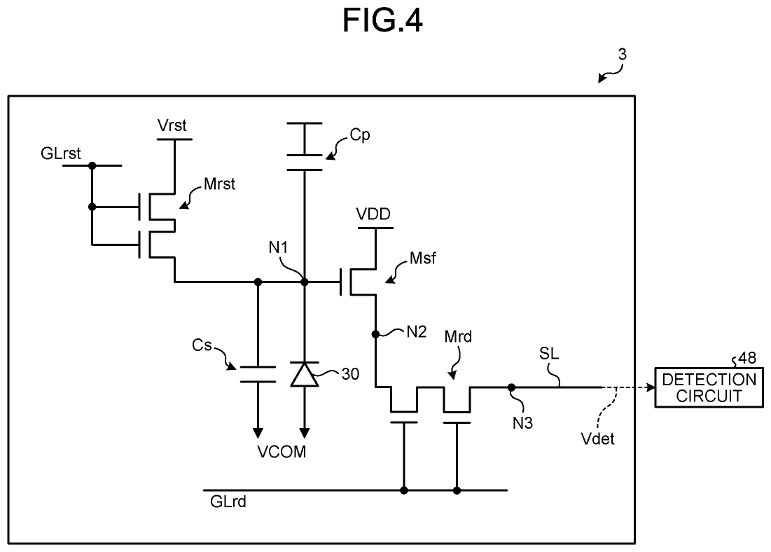

The substrate 21 is electrically coupled to a control substrate 101 through a wiring substrate 110. The wiring substrate 110 is, for example, a flexible printed circuit board or a rigid circuit board. The wiring substrate 110 is provided with the detection circuit 48. The control substrate 101 is provided with the control circuit 102 and the power supply circuit 103. The control circuit 102 is, for example, a field-programmable gate array (FPGA). The control circuit 102 supplies control signals to the sensor 10, the scan line drive circuit 15, and the signal line selection circuit 16 to control detecting operations of the sensor 10. The power supply circuit 103 supplies voltage signals including, for example, a power supply potential VDD and a reference potential VCOM (refer to FIG. 4) to the sensor 10, the scan line drive circuit 15, and the signal line selection circuit 16. Although the present embodiment exemplifies the case of disposing the detection circuit 48 on the wiring substrate 110, the present disclosure is not limited to this case. The detection circuit 48 may be disposed on the substrate 21.

The substrate 21 has the detection region AA and a peripheral region GA. The detection region AA is a region overlapping a plurality of detection elements 3 included in the sensor 10. The peripheral region GA is a region outside the detection region AA and is a region not overlapping the detection elements 3. That is, the peripheral region GA is a region between the outer perimeter of the detection region AA and outer edges of the substrate 21. The scan line drive circuit 15 and the signal line selection circuit 16 are provided in the peripheral region GA.

Each of the detection elements 3 of the sensor 10 is a photosensor including a photoelectric conversion element 30. The photoelectric conversion element 30 is a photodiode, and outputs an electrical signal corresponding to light irradiating each of the photoelectric conversion elements 30. More specifically, the photoelectric conversion element 30 is a positive-intrinsic-negative (PIN) photodiode. The detection elements 3 are arranged in a matrix having a row-column configuration in the detection region AA. The photoelectric conversion element 30 included in each of the detection elements 3 performs the detection in accordance with a gate drive signal (for example, a reset control signal RST or a read control signal RD) supplied from the scan line drive circuit 15. Each of the photoelectric conversion elements 30 outputs the electrical signal corresponding to the light irradiating the photoelectric conversion element 30 as a detection signal Vdet to the signal line selection circuit 16. The detection device 1 detects the information on the living body based on the detection signals Vdet received from the photoelectric conversion elements 30.

The scan line drive circuit 15 and the signal line selection circuit 16 are provided in the peripheral region GA. Specifically, the scan line drive circuit 15 is provided in a region extending along a second direction Dy in the peripheral region GA; and the signal line selection circuit 16 is provided in a region extending along a first direction Dx in the peripheral region GA, and is provided between the sensor 10 and the detection circuit 48.

The first direction Dx is one direction in a plane parallel to the substrate 21. The second direction Dy is another direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to the substrate 21.

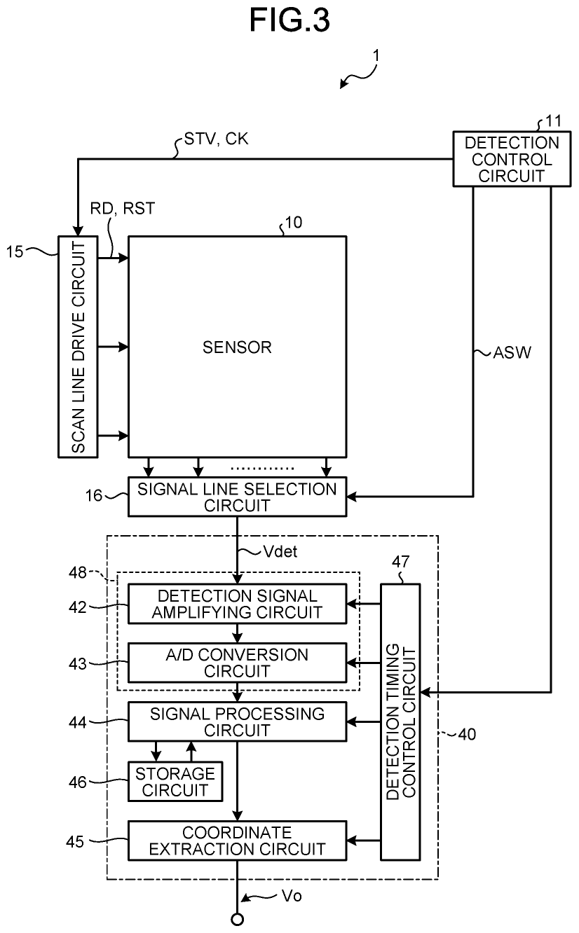

FIG. 3 is a block diagram illustrating a configuration example of the detection device according to the first embodiment. As illustrated in FIG. 3, the detection device 1 further includes a detection control circuit 11 and a detector 40. One, some, or all functions of the detection control circuit 11 are included in the control circuit 102. One, some, or all functions of the detector 40 other than those of the detection circuit 48 are also included in the control circuit 102.

The detection control circuit 11 supplies control signals to the scan line drive circuit 15, the signal line selection circuit 16, and the detector 40 to control operations of these components. The detection control circuit 11 supplies various control signals including, for example, a start signal STV and a clock signal CK to the scan line drive circuit 15. The detection control circuit 11 also supplies various control signals including, for example, a selection signal ASW to the signal line selection circuit 16.

The scan line drive circuit 15 drives a plurality of scan lines (read control scan line GLrd and reset control scan lines GLrst (refer to FIG. 4)) based on the various control signals. The scan line drive circuit 15 sequentially or simultaneously selects the scan lines and supplies the gate drive signal (for example, the reset control signal RST or the read control signal RD) to the selected scan lines. Through this operation, the scan line drive circuit 15 selects the photoelectric conversion elements 30 coupled to the scan lines.

The signal line selection circuit 16 is a switching circuit that sequentially or simultaneously selects output signal lines SL (refer to FIG. 4). The signal line selection circuit 16 is, for example, a multiplexer. The signal line selection circuit 16 couples the selected output signal lines SL to the detection circuit 48 based on the selection signal ASW supplied from the detection control circuit 11. Through this operation, the signal line selection circuit 16 outputs the detection signal Vdet of the photoelectric conversion element 30 to the detector 40.

The detector 40 includes the detection circuit 48, a signal processing circuit 44, a coordinate extraction circuit 45, a storage circuit 46, and a detection timing control circuit 47. The detection timing control circuit 47 performs control to cause the detection circuit 48, the signal processing circuit 44, and the coordinate extraction circuit 45 to operate in synchronization with one another based on a control signal supplied from the detection control circuit 11.

The detection circuit 48 is, for example, an analog front end (AFE) circuit. The detection circuit 48 is a signal processing circuit having functions of at least a detection signal amplifying circuit 42 and an analog-to-digital (A/D) conversion circuit 43. The detection signal amplifying circuit 42 is a circuit that amplifies the detection signal Vdet, and is, for example, an integration circuit. The A/D conversion circuit 43 converts an analog signal output from the detection signal amplifying circuit 42 into a digital signal.

The signal processing circuit 44 is a logic circuit that detects a predetermined physical quantity received by the sensor 10 based on output signals of the detection circuit 48. The signal processing circuit 44 can detect asperities on a surface of the finger Fg or a palm based on the signals from the detection circuit 48 when the finger Fg is in contact with or in proximity to a detection surface. The signal processing circuit 44 may detect the information on the living body based on the signals from the detection circuit 48. Examples of the information on the living body include a blood vessel image, a pulse wave, pulsation, and blood oxygen saturation of the finger Fg or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger Fg or the like when the contact or proximity of the finger Fg is detected by the signal processing circuit 44. The coordinate extraction circuit 45 is the logic circuit that also obtains detected coordinates of blood vessels of the finger Fg or the palm. The coordinate extraction circuit 45 combines the detection signals Vdet output from the respective detection elements 3 of the sensor 10 to generate two-dimensional information representing a shape of the asperities on the surface of the finger Fg or the like. The coordinate extraction circuit 45 may output the detection signals Vdet as sensor outputs Vo instead of calculating the detected coordinates.

The following describes a circuit configuration example and an operation example of the detection device 1. FIG. 4 is a circuit diagram illustrating the detection element. As illustrated in FIG. 4, each of the detection elements 3 includes the photoelectric conversion element 30, a reset transistor Mrst, a read transistor Mrd, and a source follower transistor Msf. The detection elements 3 are provided with the reset control scan lines GLrst and the read control scan lines GLrd as detection drive lines (scan lines), and provided with the output signal lines SL as wiring for reading signals.

FIG. 4 illustrates one of the detection elements 3. However, the reset control scan lines GLrst, the read control scan lines GLrd, and the output signal lines SL are each coupled to a plurality of the detection elements 3. Specifically, the reset control scan lines GLrst and the read control scan lines GLrd extend in the first direction Dx (refer to FIG. 2), and are each coupled to the detection elements 3 arranged in the first direction Dx; and the output signal lines SL extend in the second direction Dy, and are each coupled to the detection elements 3 arranged in the second direction Dy.

The reset transistor Mrst, the read transistor Mrd, and the source follower transistor (drain ground circuit) Msf are provided corresponding to each of the photoelectric conversion elements 30. Each of the transistors included in the detection element 3 is fabricated from an n-type thin-film transistor (TFT). However, each of the transistors is not limited thereto, and may be fabricated from a p-type TFT.

The reference potential VCOM is applied to an anode of the photoelectric conversion element 30. A cathode of the photoelectric conversion element 30 is coupled to a node N1. The node N1 is coupled to a capacitive element Cs, one of the source and the drain of the reset transistor Mrst, and the gate of the source follower transistor Msf. The node N1 further has parasitic capacitance Cp. When light irradiates the photoelectric conversion element 30, a signal (electrical charge) output from the photoelectric conversion element 30 is stored in the capacitive element Cs.

The gates of the reset transistor Mrst are coupled to the reset control scan line GLrst. The other of the source and the drain of the reset transistor Mrst is supplied with a reset potential Vrst. When the reset transistor Mrst is turned on (into a conduction state) in response to the reset control signal RST, the potential of the node N1 is reset to the reset potential Vrst. The reference potential VCOM is lower than the reset potential Vrst, and the photoelectric conversion element 30 is driven in a reverse bias state.

The source follower transistor Msf is coupled between a terminal supplied with the power supply potential VDD and the read transistor Mrd (node N2). The drain of the source follower transistor Msf is coupled to the power supply potential VDD. The power supply potential VDD is higher than the reset potential Vrst. The gate of the source follower transistor Msf is coupled to the node N1. The gate of the source follower transistor Msf is supplied with the signal (electrical charge) generated by the photoelectric conversion element 30. This operation causes the source follower transistor Msf to output a signal voltage corresponding to the signal (electrical charge) generated by the photoelectric conversion element 30 to the read transistor Mrd.

The read transistor Mrd is coupled between the source of the source follower transistor Msf (node N2) and the output signal line SL (node N3). The gates of the read transistor Mrd are coupled to the read control scan line GLrd. When the read transistor Mrd is turned on in response to the read control signal RD, the signal output from the source follower transistor Msf, that is, the signal voltage corresponding to the signal (electrical charge) generated by the photoelectric conversion element 30 is output as the detection signal Vdet to the output signal line SL.

In the example illustrated in FIG. 4, the reset transistor Mrst and the read transistor Mrd each have what is called a double-gate structure configured by coupling two transistors in series. However, the reset transistor Mrst and the read transistor Mrd are not limited to this structure and may have a single-gate structure or a structure configured by coupling three or more transistors in series. The circuit of each of the detection elements 3 is not limited to the configuration including the three transistors of the reset transistor Mrst, the source follower transistor Msf, and the read transistor Mrd. The detection element 3 may have two transistors or four or more transistors. Each of the reset transistor Mrst and the read transistor Mrd serves as what is called a switching element. However, not only an n-type metal-oxide-semiconductor (NMOS) switching element, but also a p-type metal-oxide-semiconductor (PMOS) switching element and a complementary metal-oxide-semiconductor (CMOS) switching element can be employed.

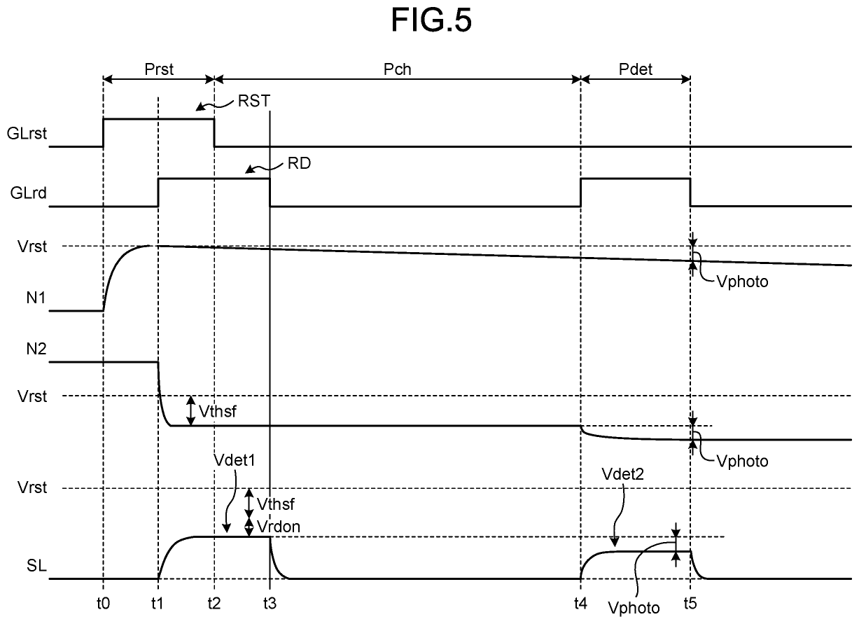

FIG. 5 is a timing waveform diagram illustrating an operation example of the detection element. The detection elements 3 perform the detection in the order of a reset period Prst, a storage period Pch, and a read period Pdet. The power supply circuit 103 supplies the reference potential VCOM to the anodes of the photoelectric conversion elements 30 over the reset period Prst, the storage period Pch, and the read period Pdet.

At time t0, the control circuit 102 sets the reset control signal RST that is supplied to the reset control scan lines GLrst to HIGH (high-level voltage) to start the reset period Prst. In the reset period Prst, each of the reset transistors Mrst is turned on (into the conduction state), thereby increasing the potential of the node N1 to the reset potential Vrst. The read transistor Mrd is off (in a nonconduction state). Hence, the source of the source follower transistor Msf is charged by the power supply potential VDD, thereby increasing the potential of the node N2.

At time t1, the control circuit 102 sets the read control signal RD that is supplied to the read control scan lines GLrd to HIGH (high-level voltage). As a result, each of the read transistors Mrd is turned on (into the conduction state), whereby the potential of the node N2 is set to (Vrst-Vthsf). Vthsf denotes a threshold voltage Vthsf of the source follower transistor Msf.

At time t2, the control circuit 102 sets the reset control signal RST to LOW (low-level voltage) to end the reset period Prst and start the storage period Pch. In the storage period Pch, the reset transistor Mrst is turned off (into the nonconduction state). The signal corresponding to the light irradiating the photoelectric conversion element 30 is stored, thereby reducing the potential of the node N1 to (Vrst-Vphoto). Vphoto denotes a signal (voltage change amount) corresponding to the light irradiating the photoelectric conversion element 30.

At time t3, the potential of a detection signal Vdet1 that is output from the output signal line SL is set to (Vrst-Vthsf-Vrdon). Vrdon denotes a voltage drop caused by on-resistance of the read transistor Mrd.

At time t3, the control circuit 102 sets the read control signal RD to LOW (low-level voltage). As a result, the read transistor Mrd is turned off (into the non-conduction state), whereby set the potential of the node N2 is set to be constant at (Vrst-Vthsf). The potential of the detection signal Vdet that is output from the output signal line SL is also set to LOW (low-level voltage).

At time t4, the control circuit 102 sets the read control signal RD(n) to HIGH (high-level voltage). As a result, the read transistor Mrd is turned on (into the conduction state) to end the storage period Pch and start the read period Pdet. The potential of the node N2 changes to (Vrst-Vthsf-Vphoto) in response to the signal Vphoto. The potential of the detection signal Vdet2 that is output in the read period Pdet decreases by an amount of the signal Vphoto from the potential of the detection signal Vdet1 obtained at time t3 and is set to (Vrst-Vthsf-Vrdon-Vphoto).

The detector 40 can detect the light irradiating the photoelectric conversion element 30 (more specifically, the amount of the light received by the photoelectric conversion element 30 during the above-described exposure period (storage period Pch)) based on the signal (Vphoto) of the difference between the detection signal Vdet1 at time t3 and the detection signal Vdet2 at time t5. While FIG. 5 illustrates the operation example of one of the detection elements 3, the scan line drive circuit 15 can cause the detection elements 3 in the entire detection region AA to perform the detection by sequentially scanning the reset control scan lines GLrst and the read control scan lines GLrd in a time division manner.

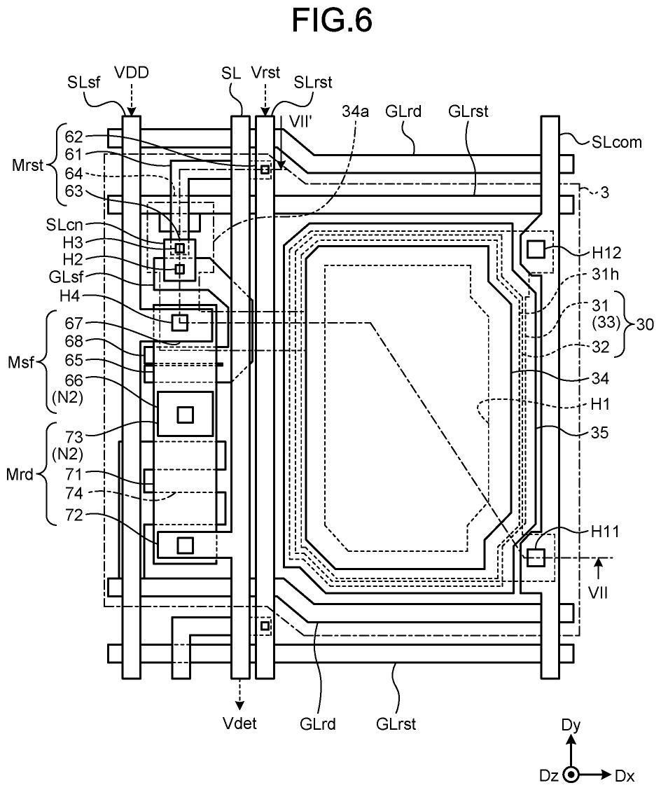

The following describes a planar configuration and a sectional configuration of the detection element 3. FIG. 6 is a plan view illustrating the detection element. As illustrated in FIG. 6, each of the detection elements 3 includes two scan lines (the read control scan line GLrd and the reset control scan line GLrst) and four signal lines (the output signal line SL, a power supply signal line SLsf, a reset signal line SLrst, and a reference signal line SLcom).

The read control scan line GLrd and the reset control scan line GLrst extend in the first direction Dx, and are arranged in the second direction Dy. The output signal line SL, the power supply signal line SLsf, the reset signal line SLrst, and the reference signal line SLcom extend in the second direction Dy, and are arranged in the first direction Dx.

The detection element 3 is a region surrounded by the two scan lines (the read control scan line GLrd and the reset control scan line GLrst) and two of the signal lines (for example, the power supply signal line SLsf and the reference signal line SLcom).

The photoelectric conversion element 30 is provided in a region surrounded by the read control scan line GLrd, the reset control scan line GLrst, the reset signal line SLrst, and the reference signal line SLcom. The photoelectric conversion element 30 is configured such that the photoelectric conversion element 30 includes a semiconductor layer having a photovoltaic effect. Specifically, the semiconductor layers of the photoelectric conversion element 30 include an i-type semiconductor layer 31, an n-type semiconductor layer 32, and a p-type semiconductor layer 33. The i-type semiconductor layer 31, the n-type semiconductor layer 32, and the p-type semiconductor layer 33 are formed of, for example, amorphous silicon (a-Si). The material of the semiconductor layers is not limited thereto and may be, for example, polysilicon or microcrystalline silicon.

The a-Si of the n-type semiconductor layer 32 is doped with impurities to form an n+ region. The a-Si of the p-type semiconductor layer 33 is doped with impurities to form a p+ region. The i-type semiconductor layer 31 is, for example, a non-doped intrinsic semiconductor, and has lower conductivity than those of the n-type semiconductor layer 32 and the p-type semiconductor layer 33.

The p-type semiconductor layer 33 is coupled to the reference signal line SLcom through a contact hole H11. With this configuration, the p-type semiconductor layer 33 of the photoelectric conversion element 30 is supplied with the reference potential VCOM through the reference signal line SLcom.

A lower conductive layer 35 is provided in a region overlapping the semiconductor layers of the photoelectric conversion element 30. The lower conductive layer 35 is coupled to the reference signal line SLcom through a contact hole H12. With this configuration, the lower conductive layer 35 is supplied with the same reference potential VCOM as that for the p-type semiconductor layer 33, and thus can reduce the parasitic capacitance between the lower conductive layer 35 and the p-type semiconductor layer 33.

The reset transistor Mrst, the source follower transistor Msf, and the read transistor Mrd are arranged in the second direction Dy. The three transistors are arranged so as to be adjacent in the first direction Dx to the photoelectric conversion element 30.

The reset transistor Mrst includes a semiconductor layer 61, a source electrode 62, a drain electrode 63, and a gate electrode 64. One end of the semiconductor layer 61 is coupled to the reset signal line SLrst. The other end of the semiconductor layer 61 is coupled to coupling wiring SLcn through a contact hole H3. A portion of the reset signal line SLrst coupled to the semiconductor layer 61 serves as the source electrode 62, and a portion of the coupling wiring SLcn coupled to the semiconductor layer 61 serves as the drain electrode 63. The semiconductor layer 61 intersects the reset control scan line GLrst. A channel region is formed at a portion of the semiconductor layer 61 overlapping the reset control scan line GLrst, and a portion of the reset control scan line GLrst overlapping the semiconductor layer 61 serves as the gate electrode 64.

The source follower transistor Msf includes a semiconductor layer 65, a source electrode 66, a drain electrode 67, and a gate electrode 68. One end of the semiconductor layer 65 is coupled to the power supply signal line SLsf through a contact hole H4. The other end of the semiconductor layer 65 is coupled to the node N2. A portion of the power supply signal line SLsf coupled to the semiconductor layer 65 serves as the drain electrode 67, and a portion of the node N2 coupled to the semiconductor layer 65 serves as the source electrode 66.

One end of a gate line GLsf is coupled to the coupling wiring SLcn through a contact hole. The other end of the gate line GLsf is branched into two portions, which are provided to be arranged in the second direction Dy. The semiconductor layer 65 intersects the gate line GLsf branched into the two portions. A portion of the gate line GLsf overlapping the semiconductor layer 65 serves as the gate electrode 68. That is, the reset transistor Mrst is electrically coupled to the gate of the source follower transistor Msf through the gate line GLsf.

An upper electrode 34 provided on the photoelectric conversion element 30 is coupled to coupling wiring 34a indicated by a long dashed double-short dashed line. The coupling wiring 34a is coupled to the coupling wiring SLcn through a contact hole H2. With this configuration, the cathode (n-type semiconductor layer 32) of the photoelectric conversion element 30 is electrically coupled to the reset transistor Mrst and the source follower transistor Msf through the coupling wiring SLcn. For example, a multilayered structure of molybdenum (Mo) and aluminum (Al) can be employed as the coupling wiring 34a. However, the coupling wiring 34a is not limited thereto and may be made of another metal material. Alternatively, the upper electrode 34 and the coupling wiring 34a may be integrally formed of a light-transmitting conductive material such as indium tin oxide (ITO).

The read transistor Mrd includes a semiconductor layer 71, a source electrode 72, a drain electrode 73, and gate electrodes 74. One end of the semiconductor layer 71 is coupled to the node N2. The other end of the semiconductor layer 71 is coupled to the output signal line SL. In other words, a portion of the node N2 coupled to the semiconductor layer 71 serves as the drain electrode 73, and a portion of the output signal line SL coupled to the semiconductor layer 71 serves as the source electrode 72. The read control scan line GLrd has two branched portions provided so as to be arranged in the second direction Dy. The semiconductor layer 71 intersects the two branched portions of the read control scan line GLrd. The portions of the read control scan line GLrd overlapping the semiconductor layer 71 serve as the gate electrodes 74. With the above-described configuration, the source follower transistor Msf and the read transistor Mrd are coupled to the output signal line SL.

The planar configuration of the photoelectric conversion element 30 and the transistors illustrated in FIG. 6 is merely an example and may be changed as appropriate. For example, the transistors are not limited to being arranged in the second direction Dy. Some of the transistors may be provided in different positions from the above-described positions, for example, in such a manner that one or more of the transistors are arranged adjacent in the first direction Dx to the other transistor(s).

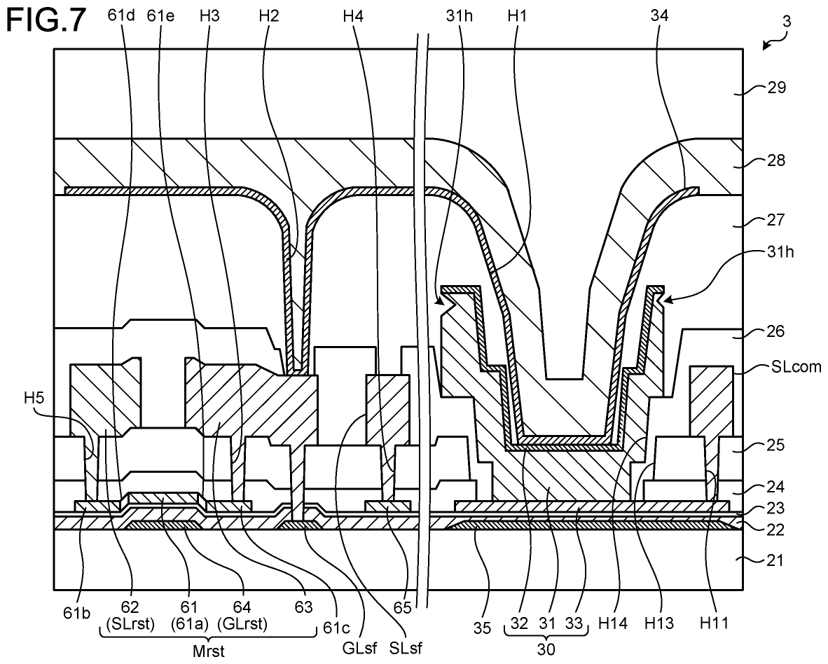

FIG. 7 is a VII-VII′ sectional view of FIG. 6. While FIG. 7 illustrates a sectional configuration of the reset transistor Mrst among the three transistors included in the detection element 3, each of the source follower transistor Msf and the read transistor Mrd also has a sectional configuration similar to that of the reset transistor Mrst.

The substrate 21 is an insulating substrate. A glass substrate of, for example, quartz or alkali-free glass, or a resin substrate of, for example, polyimide is used as the substrate 21. The gate electrode 64 is provided on the substrate 21. Insulating films 22 and 23 are provided on the substrate 21 so as to cover the gate electrode 64. The insulating films 22 and 23 and insulating films 24 to 26 are inorganic insulating films and are formed of, for example, silicon oxide (SiO₂) or silicon nitride (SiN).

The semiconductor layer 61 is provided on the insulating film 23. For example, polysilicon is used as the semiconductor layer 61. The semiconductor layer 61 is, however, not limited thereto, and may be formed of, for example, a microcrystalline oxide semiconductor, an amorphous oxide semiconductor, or low-temperature polycrystalline silicon (LTPS). The gate electrode 64 faces the semiconductor layer 61 with the insulating films 22 and 23 (gate insulating films) interposed therebetween. The reset transistor Mrst has a bottom-gate structure in which the gate electrode 64 is provided on the lower side of the semiconductor layer 61, but may have a top-gate structure in which the gate electrode 64 is provided on the upper side of the semiconductor layer 61, or a dual-gate structure in which the gate electrodes 64 are provided on the upper side and the lower side of the semiconductor layer 61.

The semiconductor layer 61 includes a channel region 61a, high impurity concentration regions 61b and 61c, and low impurity concentration regions 61d and 61e. The channel region 61a is, for example, a non-doped intrinsic semiconductor or a low-impurity region and has lower conductivity than those of the high impurity concentration regions 61b and 61c and the low impurity concentration regions 61d and 61e. The channel region 61a is provided in a region overlapping the gate electrode 64.

The high impurity concentration region 61b is provided in a region coupled to the source electrode 62, that is, in a region overlapping the bottom surface of a contact hole H5 passing through the insulating films 24 and 25. The high impurity concentration region 61c is provided in a region coupled to the drain electrode 63, that is, in a region overlapping the bottom surface of the contact hole H3 passing through the insulating films 24 and 25. A low impurity concentration region 61d is provided between the channel region 61a and the high impurity concentration region 61b. A low impurity concentration region 61e is provided between the channel region 61a and the high impurity concentration region 61c.

The insulating films 24 and 25 are provided on the insulating film 23 so as to cover the semiconductor layer 61. The source electrode 62 is coupled to the semiconductor layer 61 through the contact hole H5. The drain electrode 63 is coupled to the semiconductor layer 61 through the contact hole H3. The source electrode 62 and the drain electrode 63 are formed of, for example, a multilayered film of Ti—Al—Ti layers or Ti—Al layers that has a multilayered structure of titanium and aluminum.

The gate line GLsf coupled to the gate of the source follower transistor Msf is provided in the same layer as that of the gate electrode 64. The drain electrode 63 (coupling wiring SLcn) of the reset transistor Mrst is coupled to the gate line GLsf through a contact hole passing through the insulating films 22 to 25.

The semiconductor layer 65 of the source follower transistor Msf is provided in the same layer as the semiconductor layer 61. The power supply signal line SLsf is provided in the same layer as that of the source electrode 62 (reset signal line SLrst) and the drain electrode 63 (coupling wiring SLcn). The power supply signal line SLsf is coupled to the semiconductor layer 65 through the contact hole H4 passing through the insulating films 24 and 25.

The following describes a sectional configuration of the photoelectric conversion element 30. The lower conductive layer 35 is provided in the same layer as that of the gate electrode 64 and the gate line GLsf on the substrate 21. The insulating films 22 and 23 are provided on the lower conductive layer 35. The photoelectric conversion element 30 is provided on the insulating film 23. In other words, the lower conductive layer 35 is provided between the substrate 21 and the p-type semiconductor layer 33. More specifically, the photoelectric conversion element 30 is formed on the insulating films 22 and 23 (gate insulating films), and the lower conductive layer 35 (light-blocking layer) is provided so as to face at least the p-type semiconductor layer 33 with the insulating films 22 and 23 (gate insulating films) interposed therebetween. The lower conductive layer 35 is formed of the same material as that of the gate electrode 64 to serve as the light-blocking layer, and thus, the lower conductive layer 35 can restrain light from entering the photoelectric conversion element 30 from the substrate 21 side.

The i-type semiconductor layer 31 is provided between the p-type semiconductor layer 33 and the n-type semiconductor layer 32 in a direction orthogonal to a surface of the substrate 21 (in the third direction Dz). In the present embodiment, the p-type semiconductor layer 33, the i-type semiconductor layer 31, and the n-type semiconductor layer 32 are stacked in this order on the insulating film 23.

Specifically, the p-type semiconductor layer 33 is provided in the same layer as the semiconductor layer 61 and the semiconductor layer 65 on the insulating film 23. The insulating films 24, 25, and 26 (first insulating films) are provided so as to cover the p-type semiconductor layer 33. The insulating films 24 and 25 are provided with a contact hole H13 in a position overlapping the p-type semiconductor layer 33. The insulating film 26 is provided on the insulating film 25 so as to cover the transistors including the reset transistor Mrst. The insulating film 26 covers side surfaces of the insulating films 24 and 25 constituting an inner wall of the contact hole H13. The insulating film 26 is provided with a contact hole H14 in a position overlapping the p-type semiconductor layer 33.

The i-type semiconductor layer 31 is provided on the insulating film 26 and is coupled to the p-type semiconductor layer 33 through the contact hole H14 passing through the insulating films 24 to 26. The n-type semiconductor layer 32 is provided on the i-type semiconductor layer 31. Specifically, an upper surface of the p-type semiconductor layer 33 is in contact with the i-type semiconductor layer 31 and is also in contact with the insulating film 26 (first insulating film). A lower surface of the i-type semiconductor layer 31 is in contact with the p-type semiconductor layer 33, and side surfaces of the i-type semiconductor layer 31 are in contact with the insulating film 26 (first insulating film) and an insulating film 27 (second insulating film).

The side surface of the i-type semiconductor layer 31 is provided with a groove 31h dented in a direction orthogonal to the side surface. The groove 31h is formed at an upper end of the i-type semiconductor layer 31, that is, near a boundary between the i-type semiconductor layer 31 and the n-type semiconductor layer 32. The groove 31h is formed along an outer perimeter of the i-type semiconductor layer 31 in the plan view and is formed up to inside the outer perimeter of the n-type semiconductor layer 32. In other words, an outer edge portion of the n-type semiconductor layer 32 projects outside the bottom of the groove 31h of the i-type semiconductor layer 31 and is formed into an eave-like shape. When the photoelectric conversion element 30 is patterned for each of the detection elements 3, the groove 31h is formed by difference in etching rate between the i-type semiconductor layer 31 and the n-type semiconductor layer 32.

The insulating film 27 (second insulating film) is provided on the insulating film 26 so as to cover the photoelectric conversion element 30. The insulating film 27 is provided so as to be directly in contact with the photoelectric conversion element 30 and the insulating film 26. The insulating film 27 is formed of an organic material such as a photosensitive acrylic. The insulating film 27 is thicker than the insulating film 26. The insulating film 27 has a better step covering property than that of inorganic insulating materials and is provided so as to cover the side surfaces of the i-type semiconductor layer 31 and the n-type semiconductor layer 32 and the groove 31h.

The upper electrode 34 is provided on the insulating film 27. The upper electrode 34 is formed of, for example, a light-transmitting conductive material such as ITO. The upper electrode 34 is provided along a surface of the insulating film 27 and is coupled to the n-type semiconductor layer 32 through a contact hole H1 provided in the insulating film 27. The upper electrode 34 (coupling wiring 34a) is also electrically coupled to the drain electrode 63 of the reset transistor Mrst and the gate line GLsf through the contact hole H2 provided in the insulating film 27.

Insulating films 28 and 29 are provided on the insulating film 27 so as to cover the upper electrode 34. The insulating film 28 is an inorganic insulating film. The insulating film 28 is provided as a protective layer for restraining water from entering the photoelectric conversion element 30. The insulating film 29 is an organic protective film. The insulating film 29 is formed so as to planarize the surface of the detection device 1.

As described above, the detection device 1 of the present embodiment includes the substrate 21, the photoelectric conversion elements 30 each of which is provided on the substrate 21 and includes the semiconductor layers having a photovoltaic effect, the transistors (for example, the reset transistor Mrst) that are provided corresponding to the photoelectric conversion element 30, the first insulating films (insulating films 24, 25, and 26) that are provided on the upper side of the substrate 21 so as to cover the transistors, and the second insulating film (insulating film 27) that is provided on the upper side of the first insulating films so as to cover the photoelectric conversion element 30 and is formed of an organic material.

Since the present embodiment has the configuration in which the insulating film 27 formed of an organic material covers the photoelectric conversion element 30, ends (side surfaces) of the i-type semiconductor layer 31 and the n-type semiconductor layer 32 can be well covered even when steps are provided, for example, even when the groove 31h is formed at the ends (side surfaces) of the i-type semiconductor layer 31 and the n-type semiconductor layer 32. As a result, the upper electrode 34 can be smoothly formed on the insulating film 27 without reflecting the asperity formed by the groove 31h and the steps formed by the photoelectric conversion element 30 and the insulating film 26. As a result, disconnection of the upper electrode 34 and increase in resistance of the upper electrode 34 can be restrained, which would occur due to the uneven shape of the groove 31h and the photoelectric conversion element 30.

Since the insulating film 27 has a good covering property, the insulating film 28 provided on the upper electrode 34 restrains steps from being formed and has also a good covering property. As a result, the protective function is ensured by the insulating film 28, so that the detection device 1 can improve the reliability. Furthermore, the insulating film 29 can be planarized (the device surface can be planarized).

If an inorganic insulating film is used as the insulating film 27, the film is formed to have a thickness of approximately 0.5 μm to 0.7 μm. In the present embodiment, an organic insulating film is used as the insulating film 27. Therefore, the insulating film 27 can be thickened to have a thickness of approximately 2 μm to 3 μm, and thus, the parasitic capacitance between the upper electrode 34 and various types of wiring disposed with the insulating film 27 interposed therebetween can be reduced.

In the present embodiment, the p-type semiconductor layer 33 of the photoelectric conversion element 30 and the lower conductive layer 35 are provided in the same layers as those of the transistors. As a result, the manufacturing process can be simplified as compared with a case where the photoelectric conversion element 30 is formed in layers different from those of the transistors.

### Second Modification

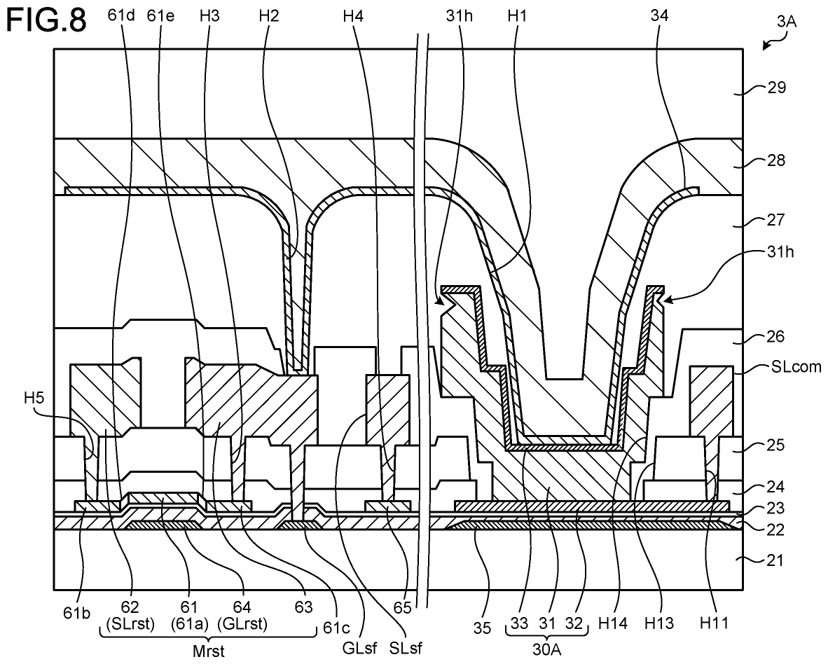

FIG. 8 is a sectional view illustrating a detection element according to a second modification of the first embodiment. In the following description, the same components as those described in the above-described embodiment are denoted by the same reference numerals and will not be described again.

As illustrated in FIG. 8, in a detection element 3A of the second modification, the stacking order in a photoelectric conversion element 30A differs from that in the first embodiment described above. Specifically, the n-type semiconductor layer 32, the i-type semiconductor layer 31, and the p-type semiconductor layer 33 are stacked in this order on the insulating film 23.

The n-type semiconductor layer 32 is provided in the same layer as the semiconductor layer 61 and the semiconductor layer 65 on the insulating film 23. The insulating films 24, 25, and 26 (first insulating films) are provided so as to cover the n-type semiconductor layer 32. The i-type semiconductor layer 31 is provided on the insulating film 26 and is coupled to the n-type semiconductor layer 32 through the contact holes H13 and H14 passing through the insulating films 24 to 26. The p-type semiconductor layer 33 is provided on the i-type semiconductor layer 31. More specifically, the photoelectric conversion element 30A is formed on the insulating films 22 and 23 (gate insulating films), and the lower conductive layer 35 (light-blocking layer) is provided so as to face at least the n-type semiconductor layer 32 with the insulating films 22 and 23 (gate insulating films) interposed therebetween. An upper surface of the n-type semiconductor layer 32 is in contact with the i-type semiconductor layer 31 and is also in contact with the insulating film 26 (first insulating film). The lower surface of the i-type semiconductor layer 31 is in contact with the n-type semiconductor layer 32, and the side surfaces of the i-type semiconductor layer 31 are in contact with the insulating film 26 (first insulating film) and the insulating film 27 (second insulating film). The semiconductor layer 61 of the reset transistor Mrst is formed in the same layer as the n-type semiconductor layer 32.

The groove 31h is formed at the upper end of the i-type semiconductor layer 31, that is, near a boundary between the i-type semiconductor layer 31 and the p-type semiconductor layer 33.

In the second modification, the n-type semiconductor layer 32 is supplied with the reference potential VCOM (refer to FIG. 4), and the p-type semiconductor layer 33 is electrically coupled to the node N1 (refer to FIG. 4). In this case, the reference potential VCOM is set to a potential higher than the reset potential Vrst such that the photoelectric conversion element 30A is driven in the reverse bias state.

### Second Embodiment

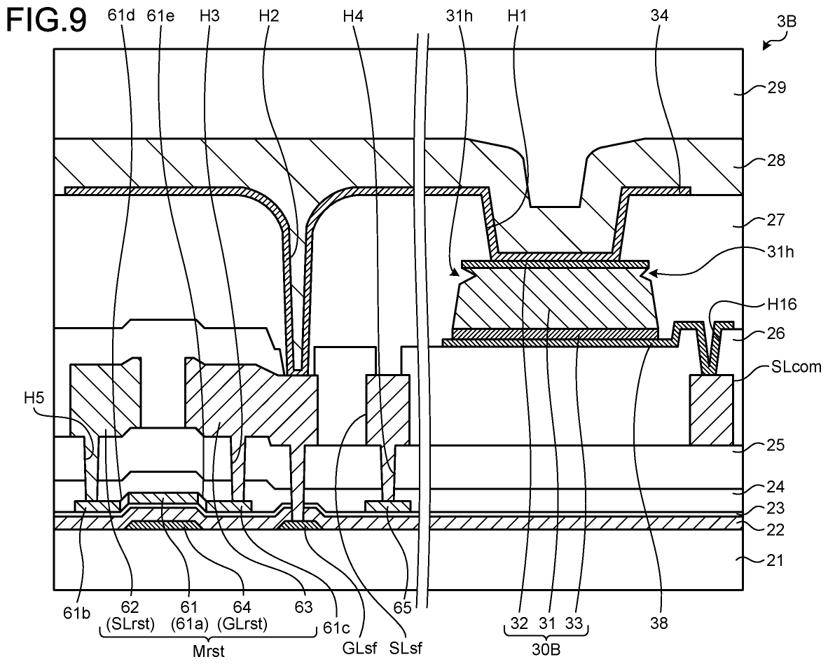

FIG. 9 is a sectional view illustrating a detection element according to a second embodiment. As illustrated in FIG. 9, the configuration of a detection element 3B of the second embodiment differs from those of the first embodiment and the second modification described above in that a photoelectric conversion element 30B is provided in layers different from those of the reset transistor Mrst.

In a region in which the photoelectric conversion element 30B is provided, no contact hole is provided in the insulating films 22 to 26, and the insulating films 22 to 26 are stacked between the substrate 21 and the photoelectric conversion element 30B. In the photoelectric conversion element 30B, the p-type semiconductor layer 33, the i-type semiconductor layer 31, and the n-type semiconductor layer 32 are stacked in this order on the insulating film 26 (first insulating film). That is, the p-type semiconductor layer 33 is provided in a layer different from that of the semiconductor layer 61 of the reset transistor Mrst.

More specifically, a lower electrode 38 is provided on a flat surface of the insulating film 26, and the p-type semiconductor layer 33 is provided on the lower electrode 38. The lower electrode 38 is coupled to the reference signal line SLcom through a contact hole H16 provided in the insulating film 26. With this configuration, the p-type semiconductor layer 33 is supplied with the reference potential VCOM from the reference signal line SLcom through the lower electrode 38.

The insulating film 27 is provided on the insulating film 26 so as to cover the photoelectric conversion element 30B. The insulating film 27 covers ends (side surfaces) of the p-type semiconductor layer 33, the i-type semiconductor layer 31, and the n-type semiconductor layer 32. Also in the present embodiment, the groove 31h is formed at the ends (side surfaces) of the i-type semiconductor layer 31, but is well covered with the insulating film 27 formed of an organic material.

### Third Modification

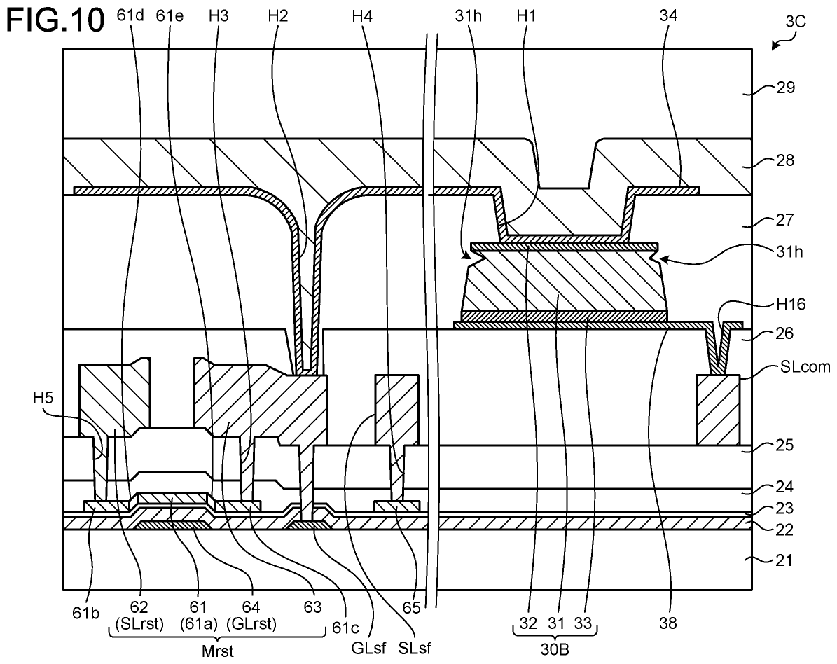

FIG. 10 is a sectional view illustrating a detection element according to a third modification of the second embodiment. A detection element 3C of the third modification differs from those of the first embodiment, the second embodiment, and the second modification described above in that the insulating film 26 is formed of an organic material.

The insulating film 26 is formed of the same material as that of the insulating film 27, that is, for example, an organic material such as a photosensitive acrylic. However, a material different from that of the insulating film 27 may be used as the insulating film 26. The insulating film 26 is provided so as to cover the transistors such as the reset transistor Mrst and various types of wiring. As a result, steps formed by the various types of wiring are planarized, and an upper surface of the insulating film 26 is flatly formed.

In the third modification, the upper electrode 34 can be more effectively restrained from being disconnected or increasing in resistance. The covering property of the insulating film 28 is also improved, and the reliability of the detection device 1 can be increased.

The photoelectric conversion element 30B of the second embodiment and the third modification can employ the same stacking configuration as that of the second modification. That is, in the photoelectric conversion element 30B, the n-type semiconductor layer 32, the i-type semiconductor layer 31, and the p-type semiconductor layer 33 may be stacked in this order on the insulating film 26 (first insulating film).

While the preferred embodiments of the present disclosure have been described above, the present disclosure is not limited to the embodiments described above. The contents disclosed in the embodiments are merely exemplary, and can be variously changed within the scope not departing from the gist of the present disclosure. Any modification appropriately made within the scope not departing from the gist of the present disclosure also naturally belongs to the technical scope of the present disclosure.

What is claimed is:

1. A detection device comprising:
a substrate;
a photoelectric conversion element that is provided to the substrate and comprises a semiconductor layer;
a transistor that is provided corresponding to the photoelectric conversion element;
a first insulating film that is provided on the substrate so as to cover the transistor; and
a second insulating film that is provided on the first insulating film so as to cover the photoelectric conversion element and is formed of an organic material.

2. The detection device according to claim 1, wherein the semiconductor layer of the photoelectric conversion element comprises:
a p-type semiconductor layer that is provided on the substrate;
an i-type semiconductor layer that is provided on the first insulating film covering the p-type semiconductor layer and is coupled to the p-type semiconductor layer through a contact hole provided in the first insulating film; and
an n-type semiconductor layer that is provided on the i-type semiconductor layer.

3. The detection device according to claim 2, wherein
a groove is provided on a side surface of the semiconductor layer,
the groove is provided on a side surface of the i-type semiconductor layer near the n-type semiconductor layer and is not provided on the n-type semiconductor layer, and
the second insulating film is provided so as to cover the side surface of the semiconductor layer and the groove.

4. The detection device according to claim 1, wherein the semiconductor layer of the photoelectric conversion element comprises:
an n-type semiconductor layer that is provided on the substrate;
an i-type semiconductor layer that is provided on the first insulating film covering the n-type semiconductor layer and is coupled to the n-type semiconductor layer through a contact hole provided in the first insulating film; and
a p-type semiconductor layer that is provided on the i-type semiconductor layer.

5. The detection device according to claim 4, wherein
a groove is provided on a side surface of the semiconductor layer,
the groove is provided on a side surface of the i-type semiconductor layer near the p-type semiconductor layer and is not provided on the p-type semiconductor layer, and
the second insulating film is provided so as to cover the side surface of the semiconductor layer and the groove.

6. The detection device according to claim 1, wherein
the semiconductor layer of the photoelectric conversion element comprises a p-type semiconductor layer, an i-type semiconductor layer, and an n-type semiconductor layer, and
the p-type semiconductor layer, the i-type semiconductor layer, and the n-type semiconductor layer are stacked in the order as listed, on an electrode provided on the first insulating film.

7. The detection device according to claim 6, wherein
a conductive layer is provided between the first insulating film and the substrate,
a contact hole is provided in a region of the first insulating film that is not overlap with the photoelectric conversion element in a plan view, and
the electrode is coupled to the conductive layer through the contact hole.

8. The detection device according to claim 1, wherein
the semiconductor layer of the photoelectric conversion element comprises a p-type semiconductor layer, an i-type semiconductor layer, and an n-type semiconductor layer, and
the n-type semiconductor layer, the i-type semiconductor layer, and the p-type semiconductor layer are stacked in the order as listed, on an electrode provided on the first insulating film.

9. The detection device according to claim 8, wherein
a conductive layer is provided between the first insulating film and the substrate,
a contact hole is provided in a region of the first insulating film that is not overlap with the photoelectric conversion element in a plan view, and
the electrode is coupled to the conductive layer through the contact hole.

10. The detection device according to claim 1, wherein the first insulating film is formed of an organic material.

11. The detection device according to claim 2, wherein the transistor comprises:
a semiconductor layer that is provided in the same layer as the p-type semiconductor layer;
a gate electrode that faces the semiconductor layer with a gate insulating film interposed therebetween; and
a source electrode and a drain electrode that are coupled to the semiconductor layer.

12. The detection device according to claim 11, wherein an upper surface of the p-type semiconductor layer is in contact with the i-type semiconductor layer and is also in contact with the first insulating film.

13. The detection device according to claim 12, wherein the i-type semiconductor layer is in contact with the p-type semiconductor layer and is also in contact with the first insulating film and the second insulating film.

14. The detection device according to of claim 11, wherein
the photoelectric conversion element is provided on the gate insulating film, and
a light-blocking layer is provided so as to face at least the p-type semiconductor layer with the gate insulating film interposed therebetween.

15. The detection device according to claim 14, wherein the light-blocking layer and the gate electrode are provided in the same layer.

16. The detection device according to claim 2, wherein
a conductive layer is provided between the first insulating film and the p-type semiconductor layer, and
the conductive layer is coupled to the p-type semiconductor layer at a position not overlapping with the photoelectric conversion element in a plan view.

17. The detection device according to claim 11, wherein
a conductive layer is provided between the first insulating film and the p-type semiconductor layer, and
the conductive layer is provided in the same layer as that of the source electrode and the drain electrode.

18. The detection device according to claim 4, wherein the transistor comprises:
a semiconductor layer that is provided in the same layer as the n-type semiconductor layer;
a gate electrode that faces the semiconductor layer with a gate insulating film interposed therebetween; and
a source electrode and a drain electrode that are coupled to the semiconductor layer.

19. The detection device according to claim 18, wherein an upper surface of the n-type semiconductor layer is in contact with the i-type semiconductor layer and is also in contact with the first insulating film.

20. The detection device according to claim 19, wherein the i-type semiconductor layer is in contact with the n-type semiconductor layer and is also in contact with the first insulating film and the second insulating film.

21. The detection device according to claim 18, wherein
the photoelectric conversion element is provided on the gate insulating film, and
a light-blocking layer is provided so as to face at least the n-type semiconductor layer with the gate insulating film interposed therebetween.

22. The detection device according to claim 21, wherein the light-blocking layer and the gate electrode are provided in the same layer.

23. The detection device according to claim 2, wherein a lowermost part of the second insulating film is located closer to the substrate than an upper surface of the first insulating film is.

24. The detection device according to claim 4, wherein a lowermost part of the second insulating film is located closer to the substrate than an upper surface of the first insulating film is.
